(19) United States
(12) Patent Application Publication
(10) Pub. No.: US 2026/0032972 A1
(43) Pub. Date: Jan. 29, 2026

(54) SEMICONDUCTOR DEVICE

(71) Applicant: Hon Young Semiconductor Corporation, Hsinchu City (TW)

(72) Inventor: Chao-Yi CHANG, Hsinchu City (TW)

(21) Appl. No.: 18/898,637

(22) Filed: Sep. 26, 2024

(30) Foreign Application Priority Data
Jul. 23, 2024 (TW) 113127602

(51) Int. Cl. H01L 29/06; H01L 29/78

(52) U.S. Cl. CPC H10D 62/107; H10D 30/665

(57) ABSTRACT

A semiconductor device includes a substrate and an epitaxial layer over the substrate. The epitaxial layer is divided into an active region, a transition region, and an edge termination region. The epitaxial layer includes a drift region in the active region, the transition region, and the edge termination region, a transition doped region in the transition region, and a termination doped region in the edge termination region. The drift region has a first conductivity type. The transition doped region and the termination doped region have a second conductivity type. A doping concentration of the termination doped region is lower than that of the transition doped region. The distance between an edge of the termination doped region away from the transition doped region and an edge of the termination doped region in contact with the transition doped region is greater than a thickness of the epitaxial layer.

### CROSS REFERENCE TO RELATED APPLICATION

This application claims priority to Taiwan Application Serial Number 113127602, filed July 23, 2024, which is herein incorporated by reference in its entirety.

### BACKGROUND

### FIELD OF DISCLOSURE

The present disclosure relates to a semiconductor device.

### DESCRIPTION OF RELATED ART

Design related to edge terminations is a critical part of design of high voltage devices. Generally, the edge terminations are designed to be wide so as to maintain high breakdown voltage. When the device requires small current, the size of the device is relatively small. The proportion of the edge terminations is high, which is not beneficial for reducing the size of the device, and thus the competitiveness of the product will be affected. Therefore, the edge termination with small width is needed.

### SUMMARY

Some embodiments of the present disclosure provide a semiconductor device includes a substrate and an epitaxial layer over the substrate. The epitaxial layer is divided into an active region, a transition region, and an edge termination region arranged along a first direction. The epitaxial layer includes a drift region in the active region, the transition region, and the edge termination region, a transition doped region in the transition region, and a first termination doped region in the edge termination region and in contact with the transition doped region. The drift region has a first conductivity type. The transition doped region has a second conductivity type different from the first conductivity type. The first termination doped region has the second conductivity type, and a doping concentration of the first termination doped region is lower than a doping concentration of the transition doped region. The distance between an edge of the termination doped region away from the transition doped region and an edge of the termination doped region in contact with the transition doped region in the first direction is greater than a thickness of the epitaxial layer in a second direction, and the second direction is substantially perpendicular to the first direction.

Some embodiments of the present disclosure provide a semiconductor device including a substrate and an epitaxial layer over the substrate. The epitaxial layer is divided into an active region, a transition region, and an edge termination region arranged along a first direction. The epitaxial layer includes a drift region in the active region, the transition region, and the edge termination region, a transition doped region in the transition region, and a plurality of first termination doped regions in the edge termination region and arranged along a second direction substantially perpendicular to the first direction in a top view. The drift region has a first conductivity type. The transition doped region has a second conductivity type different from the first conductivity type. The first termination doped regions are in contact with the transition doped region. The first termination doped regions have the second conductivity type, and a doping concentration of the first termination doped regions is lower than a doping concentration of the transition doped region.

### BRIEF DESCRIPTION OF THE DRAWINGS

FIG. 1A illustrates a cross-section view of a semiconductor device in some embodiments of the present disclosure, and FIG. 1B illustrates a top view of a transition doped region and a termination doped region in FIG. 1A.

FIG. 2A illustrates a cross-section view of a semiconductor device in some other embodiments of the present disclosure, and FIG. 2B illustrates a top view of a transition doped region and termination doped regions in FIG. 2A.

FIG. 3 illustrates a cross-section view of a semiconductor device in some other embodiments of the present disclosure.

FIG. 4A illustrates a top view of a transition doped region and termination doped regions in some embodiments of FIG. 3.

FIG. 4B illustrates a top view of the transition doped region and termination doped regions in some other embodiments of FIG. 3.

### DETAILED DESCRIPTION

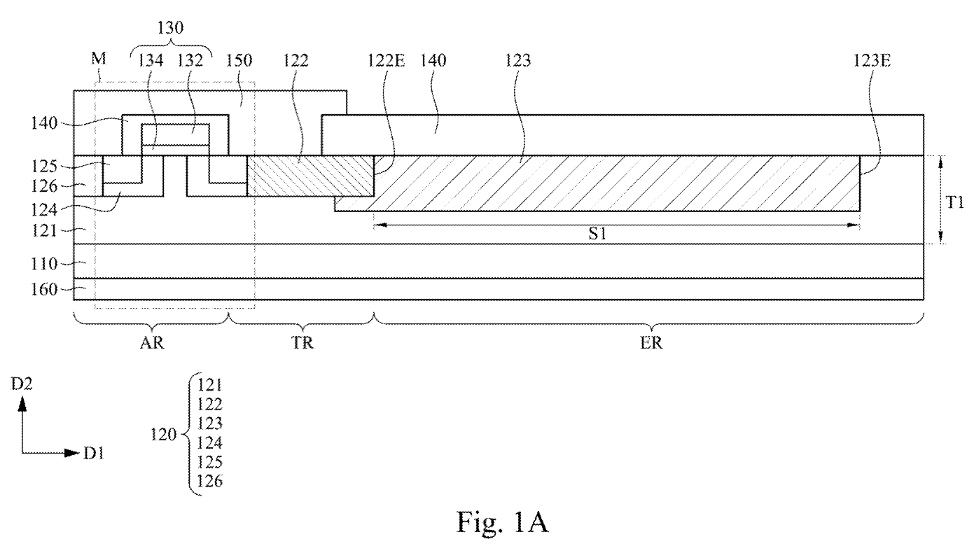

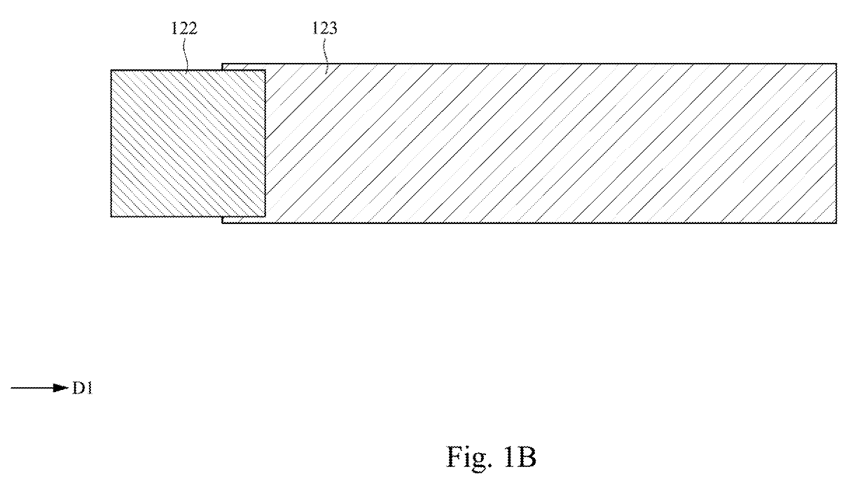

FIG. 1A illustrates a cross-section view of a semiconductor device in some embodiments of the present disclosure. FIG. 1B illustrates a top view of a transition doped region 122 and a termination doped region 123 in FIG. 1A. Referring to FIGS. 1A and 1B, the semiconductor device may include a substrate 110 and an epitaxial layer 120. The epitaxial layer 120 is over the substrate 110. The epitaxial layer 120 and the substrate 110 may be made of semiconductor material, such as silicon or silicon carbide. The epitaxial layer 120 may be divided into an active region AR, a transition region TR and an edge termination region ER. In the cross-section view (such as FIG. 1A), the active region AR, the transition region TR and the edge termination region ER are arranged along a direction D1. In some embodiments, the edge termination region ER surrounds the transition region TR, and the transition region TR surrounds the active region AR in the top view. FIG. 1A and 1B illustrate the cross-section view and the top view of the edge portion of the semiconductor device respectively. Therefore, FIG. 1A illustrates the active region AR, the transition region TR and the edge termination region ER arranged along a direction D1. The active region AR is used for accommodation of a transistor array. The edge termination region ER is used for enhancing the breakdown voltage of the semiconductor device. The transition region TR is the region connecting the active region AR and the edge termination region ER.

The epitaxial layer 120 includes a drift region 121, a transition doped region 122, and a termination doped region 123. The drift region 121 is in the active region AR, the transition region TR, and the edge termination region ER. The drift region 121 is in contact with the substrate 110, and the drift region 121 and the substrate 110 have a first conductivity type. In some embodiments, the first conductivity type may be N type. The drift region 121 is a lightly doped region, and the substrate 110 is a heavily doped region. That is, the doping concentration of the substrate 110 is higher than the doping concentration of the drift region 121.

The transition doped region 122 is in the transition region TR, and the bottom of the transition doped region 122 is in contact with the drift region 121. The top of the transition doped region 122 extends to the top surface of the epitaxial layer 120. The transition doped region 122 has a second conductivity type different from the first conductivity type. The transition doped region 122 is a heavily doped region. In some embodiments, the second conductivity type is P type.

The termination doped region 123 is in the edge termination region ER and in contact with the transition doped region 122, and the bottom of the termination doped region 123 is in contact with the drift region 121. The top of the termination doped region 123 extends to the top surface of the epitaxial layer 120. The termination doped region 123 has the second conductivity type. In some embodiments, the second conductivity type is P type. The termination doped region 123 is a lightly doped region. That is, the doping concentration of the termination doped region 123 is lower than the doping concentration of the transition doped region 122. In some embodiments, the doping concentration of the transition doped region 122 is several times to thousands of times the doping concentration of the termination doped region 123.

The epitaxial layer 120 may be formed over the substrate 110 by an epitaxial growth, and the epitaxial layer 120 may first have a first conductivity type and include ions of first conductivity type. Subsequently, an ion implantation process is performed to implant ions of second conductivity type into the epitaxial layer 120, so as to form the transition doped region 122 and the termination doped region 123 in the epitaxial layer 120. The remaining portion of the epitaxial layer 120 is the drift region 121. In some embodiments, the ions of first conductivity type may include nitrogen, phosphorous, and arsenic. The ions of second conductivity type may include boron, aluminum, and gallium.

The design of the termination doped region 123 is used to shorten the width of the edge termination region ER. Specifically, the termination doped region 123 in the present disclosure is a wide doped region. Since the termination doped region 123 and the drift region 121 are both lightly doped regions, a good charge balance is achieved between the termination doped region 123 and the drift region 121, such that a large depletion region is formed between the termination doped region 123 and the drift region 121 to improve the withstand voltage capability. As such, sufficient withstand voltage capability is provided in a small area so as to shorten the width of the edge termination region ER, thereby further reducing the size of the semiconductor device. In some embodiments, the distance S1 between the edge 123E of the termination doped region 123 away from the transition doped region 122 and the edge 122E of the termination doped region 123 in contact with the transition doped region 122 in the direction D1 is greater than the thickness of the epitaxial layer 120 in a direction D2. The direction D2 is substantially perpendicular to the direction D1. When the distance S1 between the edge 123E and the 122E of the termination doped region 123 is within the ranged disclosed above, the depletion region between the termination doped region 123 and the drift region 121 is large enough to provide sufficient withstand voltage capability. For example, the depletion region may extend to the surface of the epitaxial layer 120 to reduce the surface electric field of the epitaxial layer 120. As such, the reliability of the semiconductor device may be enhanced.

The design of the transition doped region 122 and the termination doped region 123 may be modified within the scope of the present disclosure. For example, the transition doped region 122 may partially overlap the termination doped region 123, and the depth of the termination doped region 123 may be greater than the depth of the transition doped region 122, as shown in FIG. 1A. However, the size of the overlap region between the transition doped region 122 and the termination doped region 123 is not limited. Moreover, in some other embodiments, the depth of the termination doped region 123 may be less than the depth of the transition doped region 122.

The epitaxial layer 120 further includes well regions 124, source regions 125 and body contact regions 126. The well regions 124, the source regions 125 and the body contact region 126 are in the active region AR. Some doped regions in the active region AR are in contact with the transition doped region 122 of the transition region TR. For example, the transition doped region 122 is in contact with some of the well regions 124 and some of the source regions 125. The source regions 125 have the first conductivity type, and the well regions 124 and the body contact region 126 have the second conductivity type. In some embodiments, the first conductivity type is N type, and the second conductivity type is P type. The well regions 124 are lightly and moderately doped regions, and the source regions 125 and the body contact region 126 are heavily doped regions. That is, the doping concentration of the body contact region 126 and the transition doped region 122 is higher than the doping concentration of the well regions 124 and the termination doped region 123. The doping concentration of the source regions 125 is higher than the doping concentration of the drift region 121.

The semiconductor device further includes a gate structure 130, an insulating layer 140, a source electrode 150, and a drain electrode 160. The gate structure 130 is over the active region AR of the epitaxial layer 120. The gate structure 130 includes a gate dielectric layer 132 and a gate 134. The gate dielectric layer 132 is in contact with the epitaxial layer 120, and the gate 134 is over the gate dielectric layer 132. The insulating layer 140 covers and is in contact with the gate structure 130 and the termination doped region 123 in the edge termination region ER of the epitaxial layer 120. The source electrode 150 covers the active region AR and the transition region TR of the epitaxial layer 120, and is electrically connected and in contact with the transition doped region 122, the source regions 125, and the body contact region 126. The source electrode 150 and the gate structure 130 are electrically isolated by the insulating layer 140. The drain electrode 160 is below the substrate 110 and the active region AR, the transition region TR, and the edge termination region ER of the epitaxial layer 120. In some embodiments, the gate dielectric layer 132 and the insulating layer 140 are made of dielectric material, such as silicon oxide and silicon nitride. The gate 134 is made of conductive material, such as polysilicon and metal. The source electrode 150 and the drain electrode 160 are made of conductive material, such as metal. In some embodiments, the substrate 110, the drift region 121, the well regions 124, the source regions 125, and the body contact region 126 in the active region AR of the epitaxial layer 120, the gate structure 130, the source electrode 150, and the drain electrode 160 may form a transistor M. Although FIG. 1A only illustrates a transistor M, the active region AR includes an array of transistors M actually.

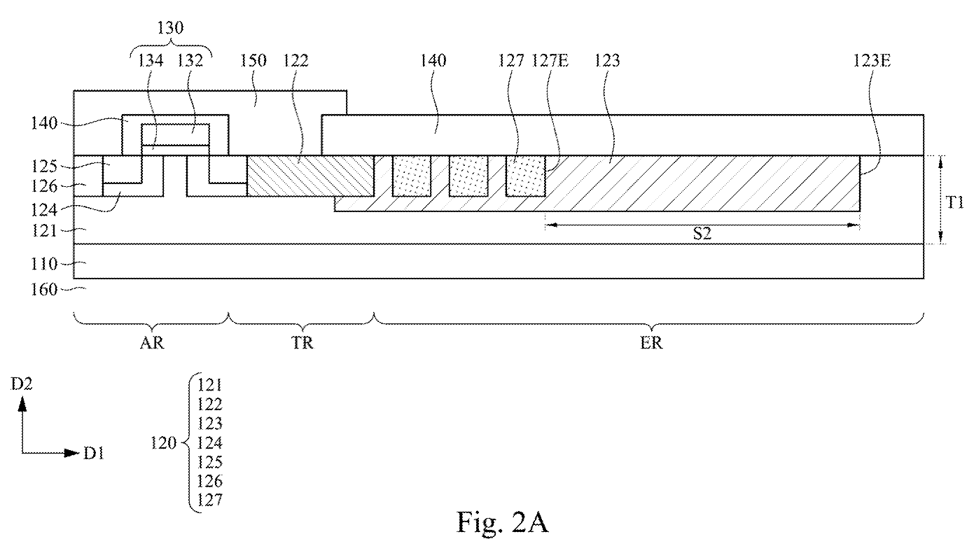

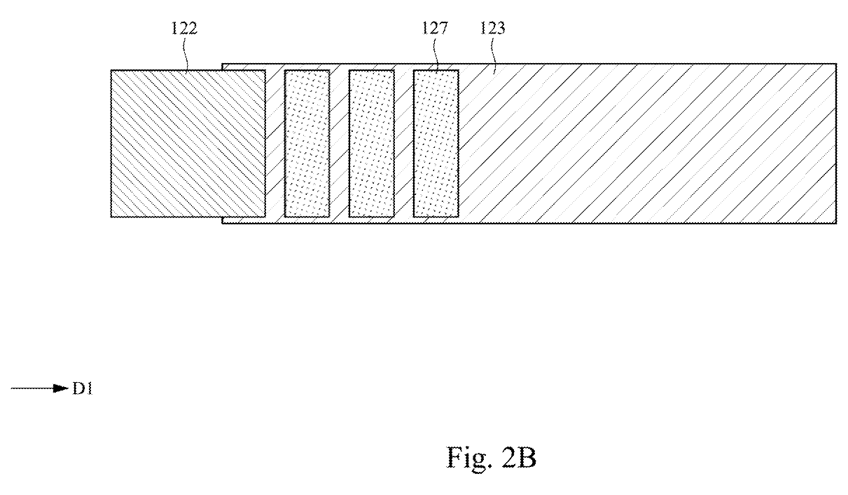

FIG. 2A illustrates a cross-section view of a semiconductor device in some other embodiments of the present disclosure. FIG. 2B illustrates a top view of the transition doped region 122, the termination doped region 123 and termination doped regions 127 in FIG. 2A. Referring to FIGS. 2A and 2B, the epitaxial layer 120 further include at least one termination doped region 127. The termination doped region 127 in the edge termination region ER overlaps the termination doped region 123. The top of the termination doped region 127 extends to the top surface of the epitaxial layer 120. The termination doped region 127 has the second conductivity type. In some embodiments, the second conductivity type is P type. The termination doped region 127 is a heavily doped region. That is, the doping concentration of the termination doped region 127 is greater than or equal to the doping concentration of the termination doped region 123. In some embodiments, the doping concentration of the termination doped region 127 is several times to thousands of times the doping concentration of the termination doped region 123. An ion implantation process may be performed to implant ions of second conductivity type into the epitaxial layer 120 so as to form the termination doped region 127. In some embodiments, the ions of second conductivity type may include boron, aluminum, and gallium.

When the number of the termination doped region 127 is 1 (for example, the termination doped region 127 only includes the one that is farthest away from the transition doped region 122 in FIG. 2A), the termination doped region 127 is spaced apart from the transition doped region 122 in the direction D1. The distance S2 between the edge 123E of the termination doped region 123 away from the transition doped region 122 and the edge 127E of the termination doped region 127 farthest away from the transition doped region 122 in the direction D1 is greater than the thickness of the epitaxial layer 120 in the direction D2. When the number of the termination doped regions 127 is more than 1 (such as 3 as shown in FIG. 2A), the termination doped regions 127 are arranged along the direction D1, and the adjacent termination doped regions 127 are spaced apart from each other in the direction D1. The distance S2 between the edge 123E of the termination doped region 123 away from the transition doped region 122 and the edge 127E of the termination doped region 127 farthest away from the transition doped region 122 in the direction D1 is greater than the thickness of the epitaxial layer 120 in the direction D2. When the distance S2 between the edge 123E of the termination doped region 123 and the edge 127E of the termination doped region 127 is within the ranged disclosed above, the depletion region between the termination doped region 123 and the drift region 121 is large enough to provide sufficient withstand voltage capability. For example, the depletion region may extend to the surface of the epitaxial layer 120 to reduce the surface electric field of the epitaxial layer 120. As such, the reliability of the semiconductor device may be enhanced. The termination doped region 127 may also help the edge depletion region to further extend, so as to improve the withstand voltage capability and stabilize the edge termination region.

The design of the transition doped region 122, the termination doped region 123, and the termination doped regions 127 may be modified within the scope of the present disclosure. For example, the depth of the termination doped region 127 may be less than the depth of the termination doped region 123. That is, the bottom of the termination doped regions 127 may be in contact with the bottom of the termination doped region 123, as shown in FIG. 2A. However, in some other embodiments, the depth of the termination doped regions 127 may be greater than the depth of the termination doped region 123. That is, the bottom of the termination doped regions 127 may be in contact with the drift region 121. Other details of the semiconductor device in FIGS. 2A and 2B are similar to the details of the semiconductor device in FIGS. 1A and 1B, and thus are not repeatedly described here.

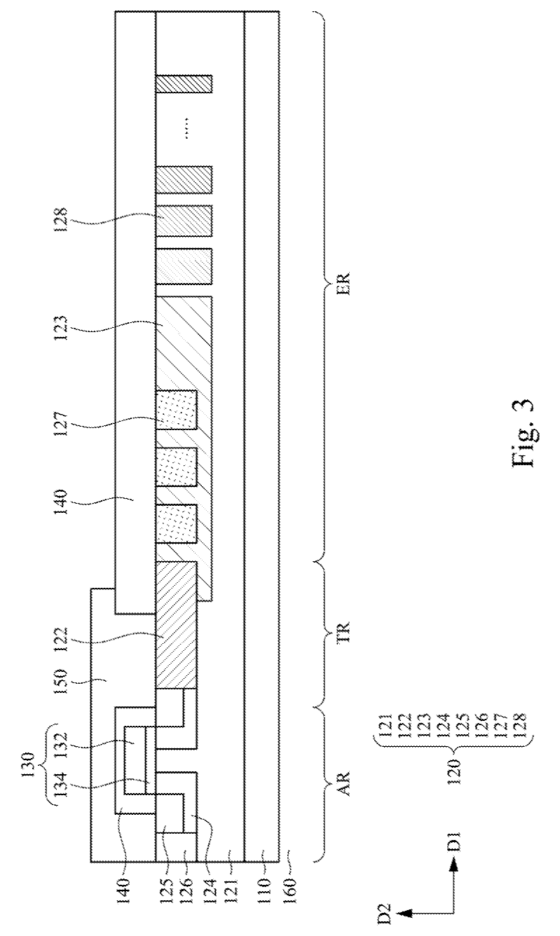

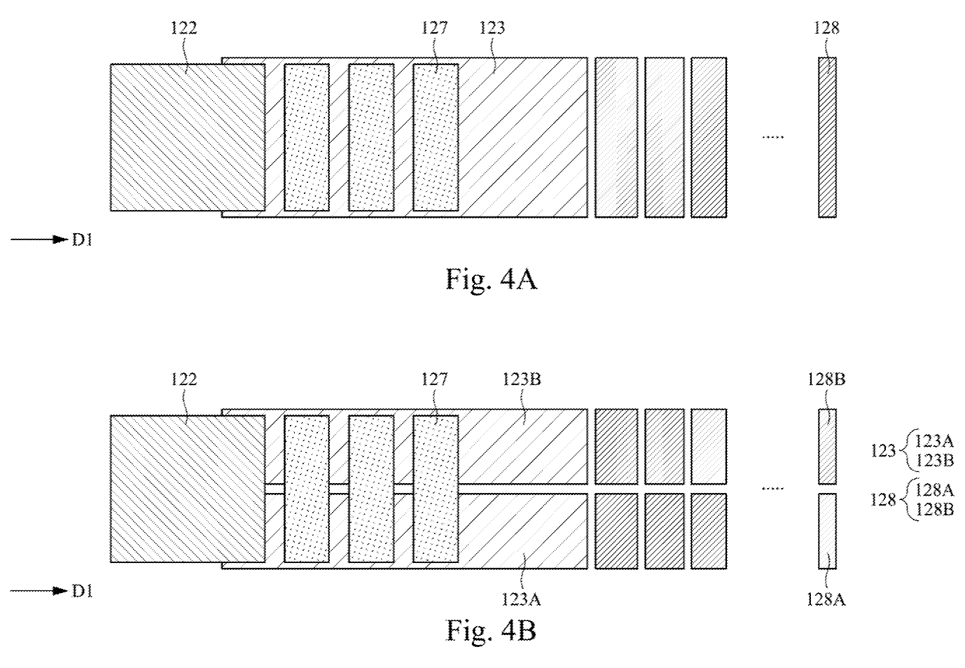

FIG. 3 illustrates a cross-section view of a semiconductor device in some other embodiments of the present disclosure. FIG. 4A illustrates a top view of the transition doped region 122, the termination doped region 123, the termination doped regions 127 and termination doped regions 128 in some embodiments of FIG. 3. FIG. 4B illustrates a top view of the transition doped region 122, the termination doped region 123, the termination doped regions 127 and termination doped regions 128 in some other embodiments of FIG. 3. Referring to FIGS. 3, 4A and 4B, the epitaxial layer 120 further includes at least one termination doped region 128. The termination doped region 128 is in the edge termination region ER, and the termination doped region 128 is at a side of the termination doped region 123 far away from the transition doped region 122. That is, the transition doped region 122, the termination doped region 123 and the termination doped region 128 are arranged along the direction D1, and the termination doped region 123 is between the transition doped region 122 and the termination doped region 128. The top of the termination doped region 128 extends to the top surface of the epitaxial layer 120. The termination doped region 128 has the second conductivity type. In some embodiments, the second conductivity type is P type. The termination doped region 127 is a lightly doped region. That is, the doping concentration of the termination doped region 128 is lower than the doping concentration of the transition doped region 122. In some embodiments, the doping concentration of the transition doped region 122 is several times to thousands of times the doping concentration of the termination doped region 128. In some embodiments, the doping concentration of the termination doped region 128 may be substantially same as the doping concentration of the termination doped region 123. An ion implantation process may be performed to implant ions of second conductivity type into the epitaxial layer 120 so as to form the termination doped region 128. In some embodiments, the ions of second conductivity type may include boron, aluminum, and gallium.

The termination doped region 128 is spaced apart from the termination doped region 123 in the direction D1. That is, the transition doped region 122, the termination doped region 123, and the termination doped region 128 are arranged along the direction D1, and in the direction D1, a semiconductor material having the conductivity type different from the conductivity type of the termination doped region 123 and the termination doped region 128 is sandwiched between the termination doped region 123 and the termination doped region 128. For example, in the direction D1, the drift region 121 of the first conductivity type is sandwiched between the termination doped region 123 and the termination doped region 128 of the second conductivity type. In the direction D1, the width of the termination doped region 128 may be less than the width of the termination doped region 123. For example, the width of the termination doped region 128 may be less than the distance S1 in FIG. 1A and the distance S2 in FIG. 2A. The termination doped region 128 may also help the edge depletion region to further extend, so as to widen the allowable range of the doping concentration (which means that the withstand voltage capability may reach a certain level or above within this range of the doping concentration).

When the number of the termination doped region 128 is more than 1, the termination doped regions 128 are arranged along the direction D1, and the adjacent termination doped regions 128 are spaced apart from each other in the direction D1. That is, in the direction D1, a semiconductor material having the conductivity type different from the conductivity type of the termination doped regions 128 is sandwiched between adjacent termination doped regions 128. For example, in the direction D1, the drift region 121 of the first conductivity type is sandwiched between the adjacent termination doped regions 128 of the second conductivity type.

The design of the transition doped region 122, the termination doped region 123, the termination doped regions 127, and the termination doped regions 128 may be modified within the scope of the present disclosure. For example, the depth of the termination doped regions 128 may be greater than the depth of the transition doped region 122 and the termination doped regions 127, and may be substantially same as the depth of the termination doped region 123. The width of the termination doped regions 128 may be smaller as being farther away from the transition doped region 122, as shown in FIG. 3. However, the present disclosure is not limited thereto. The present disclosure also does not specifically limit the distance between the termination doped regions 128 and the shape of the termination doped region 123 and the termination doped regions 128. In some embodiments, the termination doped region 123 and the termination doped region 128 are not limited to stripes and may be in any suitable shape, such as circle, square, triangle, hexagon or irregular shape.

Moreover, the termination doped regions 123 and the termination doped regions 128 may be arranged along a direction D3 perpendicular to the direction D1 and the direction D2 respectively. For example, the semiconductor device may include a plurality of the termination doped regions 123, and the termination doped regions 123 overlap the termination doped regions 127 at the same time. The termination doped regions 123 include a first region 123A and a second region 123B arranged along the direction D3, and the first region 123A is spaced apart from the second region 123B in the direction D3. That is, in the direction D3, a semiconductor material having the conductivity type different from the conductivity type of the termination doped regions 123 is sandwiched between the first region 123A and the second region 123B. For example, in the direction D3, the drift region 121 of the first conductivity type is sandwiched between the first region 123A and the second region 123B of the second conductivity type. The termination doped regions 128 include a third region 128A and a fourth region 128B arranged along the direction D3, and the third region 128A is spaced apart from the fourth region 128B in the direction D3. The third region 128A is adjacent to the first region 123A of the termination doped region 123 in the direction D1, and the fourth region 128B is adjacent to the second region 123B of the termination doped region 123 in the direction D1. That is, in the direction D3, a semiconductor material having the conductivity type different from the conductivity type of the termination doped regions 128 is sandwiched between the third region 128A and the fourth region 128B. For example, in the direction D3, the drift region 121 of the first conductivity type is sandwiched between the adjacent termination doped regions 128 of the second conductivity type. Other details of the semiconductor device in FIGS. 3, 4A and 4B are similar to the details of the semiconductor device in FIGS. 2A and 2B, and thus are not repeatedly described here.

As mentioned above, the edge termination region ER in the present disclosure includes the drift region 121 and the termination doped region 123 with great width. The conductivity type of the termination doped region 123 and the drift region 121 are different, and the termination doped region 123 and the drift region 121 are both lightly doped regions. Therefore, good charge balance is achieved. As such, the size of the edge termination region is reduced while maintaining the same level of withstand voltage capability. The surface electric field is also reduced to enhance the reliability of the device.

What is claimed is:

1. A semiconductor device, comprising:
a substrate;
an epitaxial layer over the substrate, wherein the epitaxial layer is divided into an active region, a transition region, and an edge termination region arranged along a first direction, wherein the epitaxial layer comprises:
a drift region in the active region, the transition region, and the edge termination region, and the drift region having a first conductivity type;
a transition doped region in the transition region, and the transition doped region having a second conductivity type different from the first conductivity type; and
a first termination doped region in the edge termination region and in contact with the transition doped region, the first termination doped region having the second conductivity type, and a doping concentration of the first termination doped region being lower than a doping concentration of the transition doped region, wherein a distance between an edge of the first termination doped region away from the transition doped region and an edge of the first termination doped region in contact with the transition doped region in the first direction is greater than a thickness of the epitaxial layer in a second direction, and the second direction is substantially perpendicular to the first direction.

2. The semiconductor device of claim 1, wherein the epitaxial layer further comprises:
at least a second termination doped region in the edge termination region and overlapping the first termination doped region, a doping concentration of the at least a second termination doped region being greater than the doping concentration of the first termination doped region, and the at least a second termination doped region is spaced apart from the transition doped region in the first direction, wherein a distance between the edge of the first termination doped region away from the transition doped region and an edge of the at least a second termination doped region farthest away from the transition doped region in the first direction is greater than the thickness of the epitaxial layer in the second direction.

3. The semiconductor device of claim 2, wherein the at least a second termination doped region is a plurality of second termination doped regions arranged along the first direction, and adjacent ones of the second termination doped regions are spaced apart from each other.

4. The semiconductor device of claim 2, wherein the at least a second termination doped region has the second conductivity type.

5. The semiconductor device of claim 2, wherein a depth of the at least a second termination doped region is less than a depth of the first termination doped region.

6. The semiconductor device of claim 1, wherein the epitaxial layer further comprises:
at least a third termination doped region in the edge termination region, the first termination doped region being between the transition doped region and the at least a third termination doped region, and the at least a third termination doped region being spaced apart from the first termination doped region in the first direction.

7. The semiconductor device of claim 6, wherein the at least a third termination doped region is a plurality of third termination doped regions arranged along the first direction, and adjacent ones of the third termination doped regions are spaced apart from each other.

8. A semiconductor device, comprising:
a substrate;
an epitaxial layer over the substrate, wherein the epitaxial layer is divided into an active region, a transition region, and an edge termination region arranged along a first direction, wherein the epitaxial layer comprises:
a drift region in the active region, the transition region, and the edge termination region, and the drift region having a first conductivity type;
a transition doped region in the transition region, and the transition doped region having a second conductivity type different from the first conductivity type; and
a plurality of first termination doped regions in the edge termination region and arranged along a second direction substantially perpendicular to the first direction in a top view, the first termination doped regions being in contact with the transition doped region, the first termination doped regions having the second conductivity type, and a doping concentration of the first termination doped regions being lower than a doping concentration of the transition doped region.

9. The semiconductor device of claim 8, wherein the epitaxial layer further comprises:
at least a second termination doped region in the edge termination region and overlapping the first termination doped regions.

10. The semiconductor device of claim 8, wherein the epitaxial layer further comprises:
a plurality of third termination doped regions, wherein the first termination doped regions are between the transition doped region and the third termination doped regions, and adjacent ones of the third termination doped regions are spaced apart from each other.
